(19) United States
(12) Patent Application Publication
(10) Pub. No.: US 2025/0354768 A1
(43) Pub. Date: Nov. 20, 2025

(54) RETAINING STRUCTURE

(71) Applicant: FIVEGRAND INTERNATIONAL CO., LTD., New Taipei City (TW)

(72) Inventor: TING-JUI WANG, New Taipei City (TW)

(73) Assignee: FIVEGRAND INTERNATIONAL CO., LTD., New Taipei City (TW)

(21) Appl. No.: 19/086,163

(22) Filed: Mar. 21, 2025

(30) Foreign Application Priority Data
May 17, 2024 (TW) 113118461

(51) Int. Cl. F28F 9/26

(52) U.S. Cl. CPC F28F 9/266; F28F 2275/20

(57) ABSTRACT

The present disclosure provides a retaining structure and an assembling method therefor. The retaining structure includes a main body portion, a retaining portion, an actuating portion and a radiator. The radiator can be connected to a heating element on an object, or the radiator is separated from the heating element, so as to quickly couple and separate at least two objects, achieving effects of coupling together and separating repeatedly and quickly.

### CROSS-REFERENCE TO RELATED APPLICATION

This non-provisional application claims priority under 35 U.S.C. § 119 (a) on Patent Application No(s). 113118461 filed in Taiwan, R.O.C. on May 17, 2024, the entire contents of which are hereby incorporated by reference.

### BACKGROUND OF THE INVENTION

### 1. Field of the Invention

The present disclosure relates to a retaining structure, and in particular to a retaining structure that can be used for fastening at least two objects to achieve effects of quick coupling together and easy disassembling.

### 2. Description of the Related Art

Conventionally, coupling together two objects is usually achieved by screws, and the two objects are fixed in an inseparable way to ensure coupling stability as well as prevent from mutual separating.

However, in terms of the above conventional fixing way, although the two objects are fixed and coupled together in the inseparable way, besides a situation that it is not easy to assemble, the two objects may also be difficult to disassemble due to the method of fixing and coupling by screws.

Therefore, how to invent a retaining structure to achieve a simple structure and an effect of easy to use and effectively reduce a defect of use habit will be the actively disclosed in the present disclosure.

### BRIEF SUMMARY OF THE INVENTION

In view of the above shortcomings, the inventor supposed to achieve a perfect solution and taken a deep study and finally developed a retaining structure with accumulated experience in the industry for many years, so as to achieve the purposes of quickly coupling together and easy disassembling.

In order to achieve the above purpose and other purposes, the present disclosure provides a retaining structure, and the retaining structure includes a main body portion, at least one retaining portion, at least one actuating portion and a radiator. The retaining portion is movably arranged on the main body portion; the actuating portion is arranged on the retaining portion; the radiator is arranged on the main body portion or is integrally formed with the main body portion; the radiator is provided with at least one fastening element and at least one elastomer; the fastening element is connected to an object, the object is provided with a heating element, or the object is a heating element, and the fastening element applies pressure to the radiator by way of the elastomer; the actuating portion is operated to enable the retaining portion to retain or actuate on the object, so as to define an isolation space between the radiator and the heating element, or the actuating portion is operated to release the retaining portion from retaining the object, so as to enable the radiator to apply pressure to the heating element by way of the elastomer for heat dissipation.

The present disclosure provides another retaining structure, including: a main body portion, at least one retaining portion, at least one actuating portion or a radiator. The retaining portion is movably arranged on the main body portion; the actuating portion is arranged on the retaining portion; the radiator is arranged on the main body portion or is integrally formed with the main body portion, or the radiator is provided with at least one fastening element or at least one elastomer, or the fastening element is connected to an object, or the object is provided with a heating element, or the object is a heating element; or the fastening element applies pressure to the radiator by way of the elastomer; or the actuating portion is operated to enable the retaining portion to retain or actuate on the object, or an isolation space is defined between the radiator and the heating element; or the actuating portion is operated to release the retaining portion from retaining the object, or the radiator applies pressure to the heating element by way of the elastomer for heat dissipation.

The present disclosure provides another retaining structure, including a main body portion, at least one retaining portion, at least one actuating portion and a radiator. The retaining portion is movably arranged on the main body portion; the actuating portion is arranged on the retaining portion; or the radiator is integrally formed with the main body portion or is arranged on the main body portion.

The present disclosure provides another retaining structure, including a main body portion, at least one retaining portion, or a radiator. The retaining portion is movably arranged on the main body portion; and the radiator is integrally formed with the main body portion or is arranged on the main body portion.

The present disclosure provides an assembling method for another retaining structure, including a main body portion, at least one retaining portion movably arranged on the main body portion, at least one actuating portion arranged on the retaining portion, and a radiator arranged on the main body portion, or a radiator integrally formed with the main body portion, where the radiator is provided with a fastening element and an elastomer; the fastening element is connected to an object; the object is provided with a heating element, and the fastening element applies pressure to the radiator by way of the elastomer; the actuating portion can be operated to enable the retaining portion to retain the object, so as to define an isolation space between the radiator and the heating element; or the actuating portion can be operated to release the retaining portion from retaining the object, so as to enable the radiator to apply pressure to the heating element by way of the elastomer of the fastening element for heat dissipation.

The present disclosure provides an assembling method for another retaining structure, including: connecting the fastening element to the object; applying pressure to the radiator by the fastening element using the elastomer; then operating the actuating portion to enable the retaining portion to retain the object, so as to define the isolation space between the radiator and the heating element; or operating the actuating portion to release the retaining portion from retaining the object, so as to enable the radiator to apply pressure to the heating element by way of the elastomer of the fastening element for heat dissipation.

The present disclosure provides an assembling method for another retaining structure, including a main body portion, or at least one retaining portion movably arranged on the main body portion, or at least one actuating portion arranged on the retaining portion, or a radiator arranged on the main body portion, or a radiator integrally formed with the main body portion, where the radiator is provided with a fastening element and an elastomer, or the fastening element is connected to an object, or the object is provided with a heating element, or the fastening element applies pressure to the radiator by way of the elastomer; or the actuating portion can be operated to enable the retaining portion to retain the object, so as to define an isolation space between the radiator and the heating element, or the actuating portion can be operated to release the retaining portion from retaining the object, or the radiator applies pressure to the heating element by way of the elastomer of the fastening element for heat dissipation.

The present disclosure provides an assembling method for another retaining structure including a main body portion, at least one retaining portion, at least one actuating portion or a radiator, where the retaining portion is movably arranged on the main body portion; the actuating portion is arranged on the retaining portion; or the radiator is integrally formed with the main body portion or arranged on the main body portion; or the retaining structure includes a main body portion, at least one retaining portion or a radiator; the retaining portion is movably arranged on the main body portion; or the radiator is integrally formed with the main body portion or arranged on the main body portion.

The present disclosure provides an assembling method for another retaining structure including a main body portion, at least one retaining portion or a radiator, where the radiator is integrally formed with the main body portion or arranged on the main body portion, the main body portion and an object are radiators; or the main body portion is connected to the radiator and the object is a radiator, and a heating element is held between two radiators for heat dissipation or double-sided heat dissipation.

In an embodiment of the present disclosure, the main body portion is provided with an elastic element, and the elastic element provides an elastic force for the retaining portion to retain the object or the radiator.

In an embodiment of the present disclosure, the retaining structure is provided with at least one elastomer, the main body portion is provided with an elastic element, and an elastic force of the elastic element is greater than that of the elastomer, or the elastic force of the elastomer is greater than that of the elastic element.

In an embodiment of the present disclosure, the actuating portion swirls or performs motion to drive the retaining portion to perform up-down movement or motion, or the actuating portion and the radiator are subjected to screw motion, swirling or motion to drive the retaining structure or the radiator to perform motion, up-down movement, screw labor-saving motion, lever motion, and horizontal lever labor-saving motion or motion.

In an embodiment of the present disclosure, the actuating portion swirls to limit, pause, temporarily limit or move the retaining portion to reach a rising height or a falling height.

In an embodiment of the present disclosure, two, more than two or four retaining structures are provided, and the retaining structures are respectively connected by a connecting portion, so that the retaining structures are respectively linked by the connecting portion.

In an embodiment of the present disclosure, a plurality of retaining portions are provided, the retaining portions are respectively connected by a connecting portion, the connecting portions are respectively provided with a restricting portion, and when the retaining portions or the connecting portions move, the restricting portions are used for restricting to operate the fastening element with a tool, or allowing to use the tool to operate the fastening element, or the retaining structure is provided with a restricting portion for restricting to operate the fastening element with the tool, or allowing to use the tool to operate the fastening element.

In an embodiment of the present disclosure, the main body portion and the radiator are integrally formed, assembled by expanded connecting, locking, riveting, welding and fastening, assembled or assembled by adhering.

In an embodiment of the present disclosure, the object or the heating element is an IC, a CPU, a GPU, a PCB, a computer, a server, a cabinet, an electric element, a wafer, a radiator, a data center, a memory, a metal element or a non-metal element.

In an embodiment of the present disclosure, more than one or four retaining portions and elastomers are provided, and when the retaining portions are released from retaining, the elastomers uniformly, synchronously, averagely, instantly or nearly synchronously apply pressure to the radiator, so as to enable the radiator to apply pressure to the heating element for heat dissipation.

In an embodiment of the present disclosure, the fastening element is a threaded element, an elastic fastening element, a spherical element, a spring, an outer fastening element, an inner fastening element, the radiator, the elastomer, a cylinder element, a metal element or a plastic element.

In an embodiment of the present disclosure, the radiator is provided with a fluid channel for allowing fluid to pass through for heat dissipation, or the fluid is liquid fluid, gaseous fluid or oil.

In an embodiment of the present disclosure, one, two, more than two, four or more than four retaining portions are provided, a connecting portion is arranged between every two retaining portions to retain an object, or the retaining portions are connected to the connecting portions in a bolting manner.

In an embodiment of the present disclosure, the retaining portions are inserted, buckled, entered or propped by a transverse object or an object, so as to enable the retaining portions to move or perform motion, or the retaining portions or the transverse object or the object is provided with an inclined surface, an arc surface or a lifting portion for lifting or moving the retaining portion.

In an embodiment of the present disclosure, the radiator is provided with at least one fastening element or a limiting element, and the fastening element or the limiting element is connected to an object, limits the object or retains the object so as to restrict the motion, position, motion direction, elastic motion, rotating, swirling of the radiator or prevent from rotating or swirling.

In an embodiment of the present disclosure, the actuating portion is a swirling portion, a rotating portion, a motion portion, a threaded portion, a screw thread portion and a nut portion, or swirled, rotated or locked to drive the retaining portion to perform motion, actuation or up-down motion.

In an embodiment of the present disclosure, the actuating portion is a wrenching portion, the swirling portion, the motion portion and a lever portion, or is swirled, rotated, wrenched or actuated in a lever manner, so as to drive the retaining portion to perform motion, actuation or up-down motion.

In an embodiment of the present disclosure, the actuating portion and the retaining portion are integrally formed, or the actuating portion and the retaining portion are assembled by bolting, locking, riveting, expanded connecting, welding, fastening or connecting, or the actuating portion is provided with a limiting portion for limiting, propping and restricting a stroke or restricting a distance from the actuating portion to the radiator or a joint stroke or a locking stroke.

In an embodiment of the present disclosure, the actuating portion swirls or performs motion to prop or apply pressure to the retaining portion, the retaining portion props or applies pressure to the fastening element to fasten the fastening element to the object, and pressure is applied to the heating element by an elastic force of the elastomer, or the fastening element and the retaining portion are integrally formed or formed in an assembling manner.

In an embodiment of the present disclosure, the radiator or the retaining structure is fastened or assembled to one object, where the object is also a radiator, or one or two radiators are used for heat dissipation of one or a plurality of heating elements, or two radiators are assembled by connecting or fastening.

In an embodiment of the present disclosure, the retaining portion or the main body portion is a metal element, a plastic element, a non-metal element, a support element, a rod element, a fastening element, a threaded element, a screw, a nut, an inner fastening element, an outer fastening element, an elastic fastening element, a rail element, a lever pushing element, a handle element, a telescopic element, the elastomer or the radiator.

In an embodiment of the present disclosure, the main body portion and the object are radiators, or the main body portion is connected to the radiator and the object is the radiator, where the heating element is held between the two radiators for heat dissipation or double-sided heat dissipation.

Therefore, according to the retaining structure and the assembling method therefor in the present disclosure, the radiators can be connected to the heating element of the object, or the radiators are separated from the heating element to complete quick coupling and separating of at least two objects, achieving effects of coupling together and separating repeatedly and quickly.

### BRIEF DESCRIPTION OF THE DRAWINGS

FIG. 1 is a schematic diagram of an assembling state in a Specific Embodiment I of the present disclosure

FIG. 2 is a schematic diagram of an assembling state in a Specific Embodiment II of the present disclosure.

FIG. 3 is a schematic diagram of an assembling state in a Specific Embodiment III of the present disclosure.

FIG. 4 is a schematic diagram of an assembling state in a Specific Embodiment IV of the present disclosure.

FIG. 5 is a schematic diagram of an assembling state in a Specific Embodiment V of the present disclosure.

FIG. 6 is a schematic diagram of an assembling state in a Specific Embodiment VI of the present disclosure.

FIG. 7 is a schematic diagram of an assembling state in a Specific Embodiment VII of the present disclosure.

FIG. 8 is a schematic diagram of an assembling state in a Specific Embodiment VIII of the present disclosure.

FIG. 9 is a schematic diagram of an assembling state in a Specific Embodiment IX of the present disclosure.

FIG. 10 is a schematic diagram of an assembling state in a Specific Embodiment X of the present disclosure.

FIG. 11 is a schematic diagram of an assembling state in a Specific Embodiment XI of the present disclosure.

FIG. 12 is a schematic diagram of an assembling state in a Specific Embodiment XII of the present disclosure.

FIG. 13 is a schematic diagram of an assembling state in a Specific Embodiment XIII of the present disclosure.

FIG. 14 is a schematic diagram of an assembling state in a Specific Embodiment XIV of the present disclosure.

FIG. 15 is a schematic diagram of an assembling state in a Specific Embodiment XV of the present disclosure.

FIG. 16 is a schematic diagram of an assembling state in a Specific Embodiment XVI of the present disclosure.

FIG. 17 is a schematic diagram of an assembling state in a Specific Embodiment XVII of the present disclosure.

FIG. 18 is a schematic diagram of an assembling state in a Specific Embodiment XVIII of the present disclosure.

FIG. 19 is a schematic diagram of an assembling state in a Specific Embodiment XIX of the present disclosure.

FIG. 20 is a schematic diagram of an assembling state in a Specific Embodiment XX of the present disclosure.

### DETAILED DESCRIPTION OF THE INVENTION

In order to fully understand the purpose, features and effects of the present disclosure, the present disclosure is described in detail by way of the following specific embodiments in cooperation with the accompanying drawings, as follows:

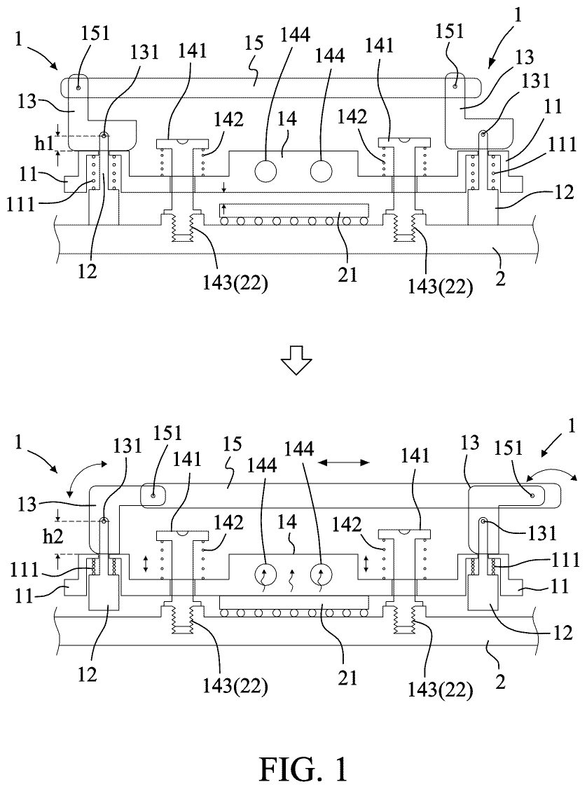

With reference to FIG. 1, as shown in the figure: the present disclosure provides a retaining structure 1, including at least a main body portion 11, at least one retaining portion 12, at least one actuating portion 13 and a radiator 14.

The retaining portion 12 is movably arranged on the main body portion 11.

The actuating portion 13 is arranged on the retaining portion 12.

The radiator 14 can be arranged on the main body portion 11 in an integral forming manner; the radiator 14 is provided with at least one fastening element 141 (or a limiting element) and at least one elastomer 142; the fastening element 141 is connected to an object 2, the object 2 is provided with a heating element 21 (or the object 2 is a heating element), and the fastening element 141 applies pressure to the radiator 14 by way of the elastomer 142; and the actuating portion 13 is operated to enable the retaining portion 12 to retain or actuate on the object 2, so as to define an isolation space s between the radiator 14 and the heating element 21, or the actuating portion 13 is operated to release the retaining portion 12 from retaining the object 2, so as to enable the radiator 14 to apply pressure to the heating element 21 by way of the elastomer 142 for heat dissipation.

Based on the above embodiment, an assembling method for the retaining structure 1 according to the present disclosure includes: operating the actuating portion 13 to enable the retaining portion 12 to retain or actuate on the object 2, so as to define the isolation space s between the radiator 14 and the heating element 21, or operating the actuating portion 13 to release the retaining portion 12 from retaining the object 2, so as to enable the radiator 14 to apply pressure to the heating element 21 by way of the elastomer 142 of the fastening element 141 for heat dissipation.

When in use, the fastening element 141 can be connected to an internal threaded portion 22 of the object 2 by way of an external threaded portion 143, and the elastomer 142 is propped between the main body portion 11 and the fastening element 141, the fastening element 141 (or the limiting element) is connected to the object 2, limit the object or retain the object so as to restrict the motion, position, motion direction, elastic motion, rotation and swirling of the radiator or prevent from rotating or swirling; and in this state, the retaining portion 12 moves out of the main body portion 11 to retain the object 2, so that the isolation space s is defined between the radiator 14 and the heating element 21; and the radiator 14 is correspondingly arranged above the heating element 21, thus finishing the assembling of the retaining structure 1 and the object 2.

After the above assembling is finished, force can be applied to operate the actuating portion 13 to retract the retaining portion 12 into the main body portion 11, so as to release the retaining portion 12 from retaining the object 2, and furthermore, the radiator 14 applies pressure to the heating element 21 by way of the elastomer 142 to make the radiator 14 and the heating element 21 in mutual contact and propping for heat dissipation. Therefore, at least two objects can be quickly coupled together and separated, achieving effects of coupling together and separating repeatedly and quickly.

Besides the above embodiments, in an embodiment of the present disclosure, the difference from the above embodiments is that the main body portion 11 is provided with an elastic element 111, two ends of the elastic element 111 are respectively propped to the main body portion 11 and the retaining portion 12, and the elastic element 111 provides elastic force for the retaining portion 12 to retain the object 2 (or the radiator 14). Therefore, the elastic force of the elastic element 111 can be used for propping the retaining portion 12 to the object 2, and when the radiator 14 is not in contact with and not propped to the heating element 21, the radiator 14 and the isolation space s can be maintained at preset positions so as to avoid mutual contact and propping between the radiator 14 and the heating element 21 when not in use.

Besides the above embodiments, in an embodiment of the present disclosure, the difference from the above embodiments is that the main body portion 11 is provided with the elastic element 111, and the elastic force of the elastic element 111 is greater than that of the elastomer 142 (or the elastic force of the elastomer 142 is greater than that of the elastic element 111). Therefore, the elastic force of the elastic element 111 can be used for propping the retaining portion 12 to the object 2 (or the radiator 14), and when the radiator 14 is not in contact with and not propped to the heating element 21, the radiator 14 and the isolation space s can be maintained at the preset positions so as to avoid mutual contact and propping between the radiator 14 and the heating element 21 when not in use; and when a force is applied to operate the actuating portion 13 to retract the retaining portion 12 into the main body portion 11, the elastic element 111 is compressed simultaneously to release the retaining portion 12 from retaining the object 2, and meanwhile, because the elastic element 111 has no elastic force applied to the retaining portion 12, the radiator 14 applies pressure to the heating element 21 by way of the elastomer 142 to enable mutual contact and propping between the radiator 14 and the heating element 21 for heat dissipation.

Besides the above embodiments, in an embodiment of the present disclosure, the difference from the above embodiments is that: the actuating portion 13 swirls or performs motion to drive the retaining portion 12 to perform up-down movement, and the actuating portion 13 swirls to limit, pause, temporarily limit or move the retaining portion 12 to reach a rising height h1 or a falling height h2; and in this embodiment, the actuating portion 13 is movably arranged on the retaining portion 12 by way of a bolting portion 131, thus the actuating portion 13 swirls or performs motion to drive the retaining portion 12 to perform up-down movement. In this embodiment of the present disclosure, when the radiator 14 is in contact with and propped to the heating element 21 to define the isolation space s, the actuating portion 13 is at the first height h 1; and when a force is applied to the actuating portion 13 to convert the actuating portion 13 from the rising height h1 to the falling height h2, the retaining portion 12 can retract into the main body portion 11, and the elastic element 111 is compressed simultaneously to release the retaining portion 12 from retaining the object 2, meanwhile, the elastic element 111 has no elastic force applied to the retaining portion 12, so that the radiator 14 applies pressure to the heating element 21 by way of the elastomer 142 to enable mutual contact and propping between the radiator 14 and the heating element 21 for heat dissipation. Therefore, at least two objects can be quickly coupled together and separated, achieving effects of coupling together and separating repeatedly and quickly.

Besides the above embodiments, in an embodiment of the present disclosure, the actuating portion 13 swirls or performs motion to drive the retaining portion 12 to perform up-down movement or motion, or the actuating portion 13 and the radiator 14 are subjected to screw motion, swirling or motion to drive the retaining structure 1 or the radiator 14 to perform motion, up-down movement, screw labor-saving motion, lever motion, and horizontal lever labor-saving motion or motion.

Besides the above embodiments, in an embodiment of the present disclosure, the difference from the above embodiments is that the object 2 or the heating element 21 can be an IC, a CPU, a GPU, a PCB, a computer, a server, a cabinet, an electric element, a wafer, a radiator, a data center, a memory, a metal element or a non-metal element. Therefore, the retaining structure 1 in the present disclosure has an effect of wide application.

Besides the above embodiments, in an embodiment of the present disclosure, the difference from the above embodiments is that two, more than two or four retaining structures 1 are provided, the retaining structures 1 are respectively connected by a connecting portion 15, so that the retaining structures 15 are respectively linked by the connecting portion 15, and the connecting portion 15 is respectively in movable coupling with the actuating portion 13 by another bolting portion 151, so that the actuating portion 13 performs motion and linkage by the bolting portion 131 and the another bolting portion 151.

Besides the above embodiments, in an embodiment of the present disclosure, the difference from the above embodiments is that more than one or four retaining portions 12 and elastomers 142 are provided, and when the retaining portions 12 are released from retaining, the elastomers 142 uniformly, synchronously, averagely, instantly or nearly synchronously apply pressure to the radiator 14, so as to enable the radiator 14 to apply pressure to the heating element 21 for heat dissipation.

Based on the embodiment, the force can be applied to one actuating portion 13 to drive the connecting portion 15 to link another actuating portion 13, so that when the actuating portions 13 are simultaneously converted from the rising height h1 to the falling height h2, the retaining portion 12 can retract into the main body portion 11, and the elastic element 111 is simultaneously compressed to release the retaining portions 12 from retaining the object 2; and meanwhile, because the elastic element 111 has no elastic force applied to the retaining portion 12, the radiator 14 applies pressure to the heating element 21 by the elastomer 142 to enable mutual contact and propping between the radiator 14 and the heating element 21 for heat dissipation. Therefore, at least two objects can be quickly coupled together and separated, achieving effects of coupling together and separating repeatedly and quickly.

Besides the above embodiments, in an embodiment of the present disclosure, the difference from the above embodiments is that the fastening element 141 can be a threaded element, an elastic fastening element, a spherical element, a spring, an outer fastening element, an inner fastening element, the radiator, the elastomer, a cylinder element, a metal element or a plastic element; and therefore, the fastening element 141 can better meet actual assembling requirements.

Besides the above embodiments, in an embodiment of the present disclosure, the difference from the above embodiments is that the radiator 14 is provided with a fluid channel 144 for allowing fluid to pass through for heat dissipation, where the fluid is liquid fluid, gaseous fluid or oil; and thus, the radiator 14 can better meet actual heat radiation requirement.

Besides the above embodiments, in an embodiment of the present disclosure, the difference from the above embodiments is that the radiator 14 (or the retaining structure 1) is fastened or assembled to the object 2, where the object 2 can also a radiator, or one or two radiators 14 are used for heat dissipation of one heating elements 21 or a plurality of heating elements 21, or two radiators 21 are assembled by connecting or fastening; in addition, the main body portion 11 and the object 2 can be radiators, or the main body portion 11 is connected to the radiator 14 and the object 2 is a radiator, where the heating element 21 is held between two radiators 14 for heat dissipation or double-sided heat dissipation; and thus, the radiators 14 can better meet actual heat radiation requirement.

Besides the above embodiments, in an embodiment of the present disclosure, the difference from the above embodiments is that the retaining portion 12 or the main body portion 11 can be a metal element, a plastic element, a non-metal element, a support element, a rod element, a fastening element, a threaded element, a screw, a nut, an inner fastening element, an outer fastening element, an elastic fastening element, a rail element, a lever pushing element, a handle element, a telescopic element, an elastomer or a radiator; and thus, the retaining portion 12 and the main body portion 11 can be better meet actual application requirements.

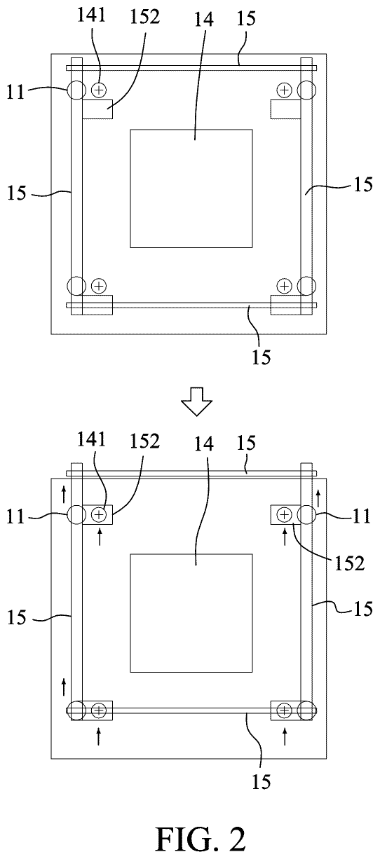

With reference to FIG. 2, as shown in the figure, besides the above embodiments, in an embodiment of the present disclosure, the difference from the above embodiments is that the retaining structure 1 is provided with a plurality of retaining portions 12, the retaining portions 12 are respectively connected by the connecting portion 15, the connecting portions 15 are respectively provided with a restricting portion 152, and when the retaining portions 12 or the connecting portions 15 move, the restricting portions are used for restricting to operate the fastening element 141 with a tool 3, or allowing to use the tool 3 to operate the fastening element 141. Thus, the restricting portions 152 can be respectively used as protection for the fastening element 141 to achieve an effect of avoiding false touch of the fastening element 141.

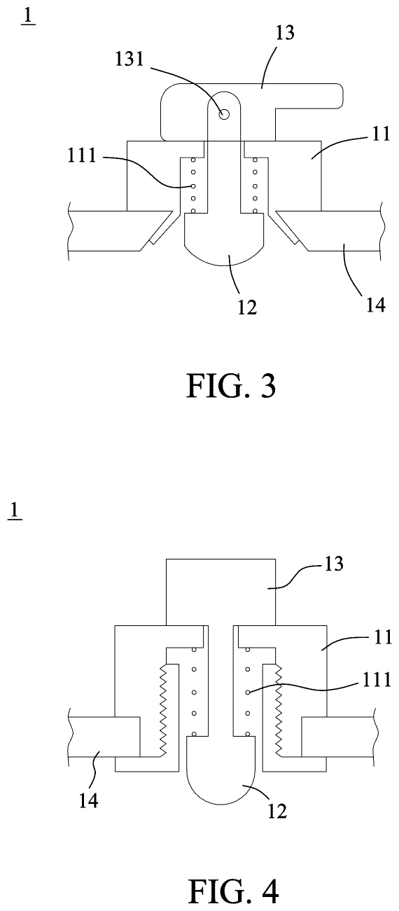

With reference to FIG. 3 and FIG. 4, as shown in the figures, besides the above embodiments, in an embodiment of the present disclosure, the difference from the above embodiments is that in addition to an integrally formed shape of the main body portion 11 and the radiator 14, the main body portion 11 and the radiator 14 can also be assembled by expanded connecting (as shown in FIG. 3), locking (as shown in FIG. 4), riveting, welding, fastening, assembled or assembled by adhering. Therefore, the main body portion 11 and the radiator 14 can be stably coupled, and actual assembling requirements can be better met in the present disclosure.

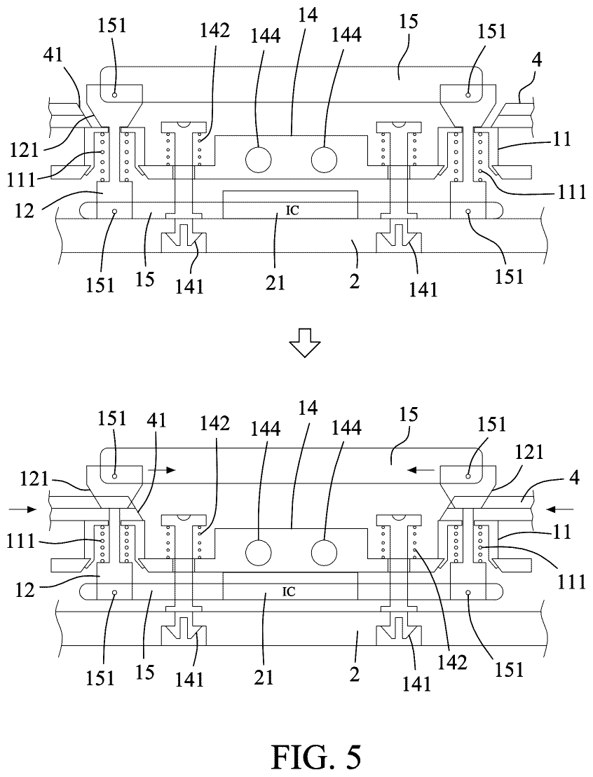

With reference to FIG. 5, as shown in the figure, besides the above embodiments, in an embodiment of the present disclosure, the difference from the above embodiments is that when one, two, more than two, four or more than four retaining portions 12 are provided, a connecting portion 15 is arranged between every two retaining portions 12 for retaining the object 2, and the retaining portions 12 are connected to the connecting portions 15 in a bolting manner by the another bolting portion 151, so that when the retaining portions 12 perform motion, the connecting portions 15 and the another bolting portion 151 can be matched to achieve a linkage effect.

Besides the above embodiments, in an embodiment of the present disclosure, the difference from the above embodiments is that the retaining portion 12 is inserted, buckled, entered or propped by a transverse object 4 (or an object 2) so as to enable the retaining portion 12 to move or perform motion, or the retaining portion 12 and the transverse object 4 are respectively provided with lifting portions 121 and 41 (or an inclined surface, and an arc surface), the lifting portion 41 of the transverse object 4 and the lifting part 121 of the retaining portions 12 are mutually matched to lift or move the retaining portion 12, thereby achieving an effect of smooth movement.

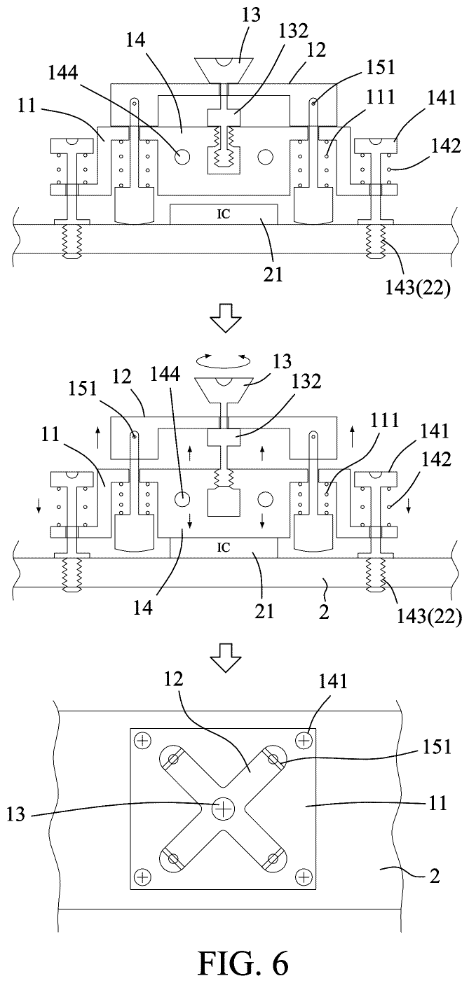

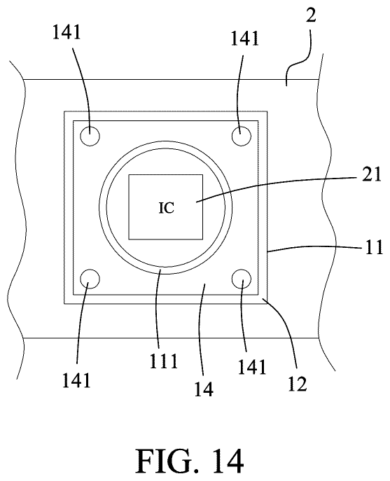

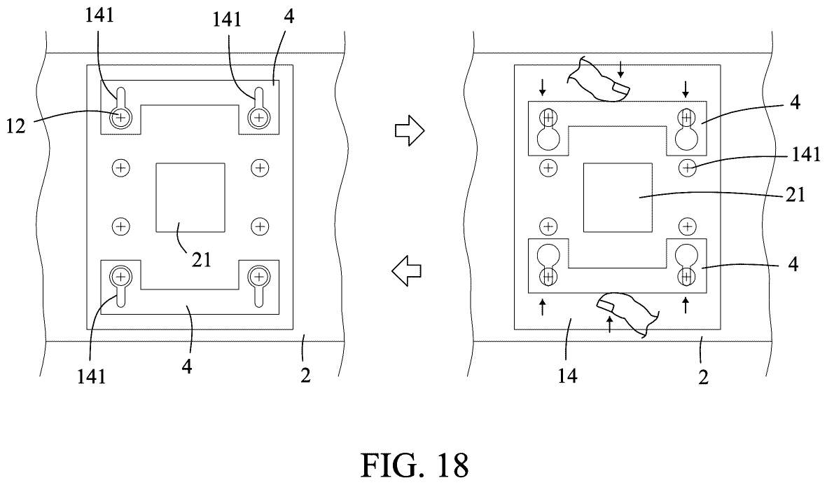

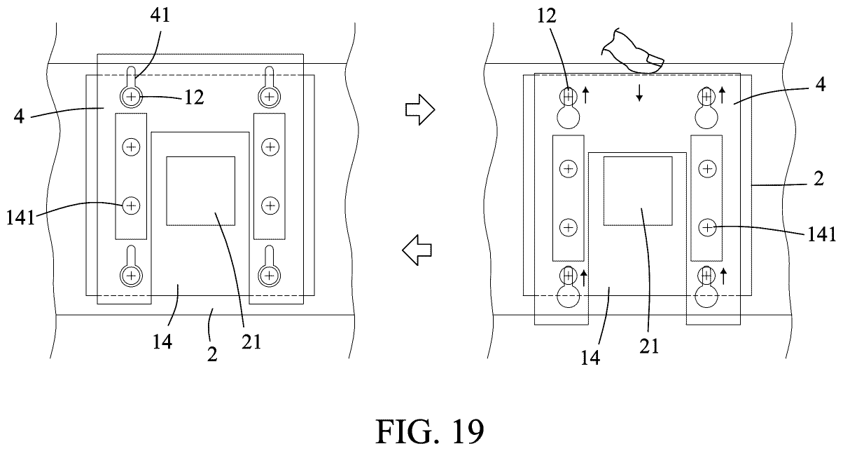

With reference to FIG. 6 to FIG. 19, as shown in the figures, besides the above embodiments, in an embodiment of the present disclosure, the difference from the above embodiments is that the actuating portion 13 can be a swirling portion, a rotating portion, a motion portion, a threaded portion, a screw thread portion and a nut portion, or swirled, rotated or locked to drive the retaining portion 12 to perform motion, actuation or up-down motion, and the main body portion 11 and the radiator 14 are integrally formed (as shown in FIG. 6 to FIG. 19); therefore, the actuating portion 13 can swirl or perform motion to enable the actuating portion 13 to prop or apply pressure to the retaining portion 12, so that the retaining portion 12 props or applies pressure to the fastening element 141 to fasten the fastening element 141 to the object 2, and the pressure is applied to the heating element 21 through the elastic force of the elastomer 142; and thus, the actuating portion 13 can be matched with the fastening element 141 to further meet actual assembling requirements.

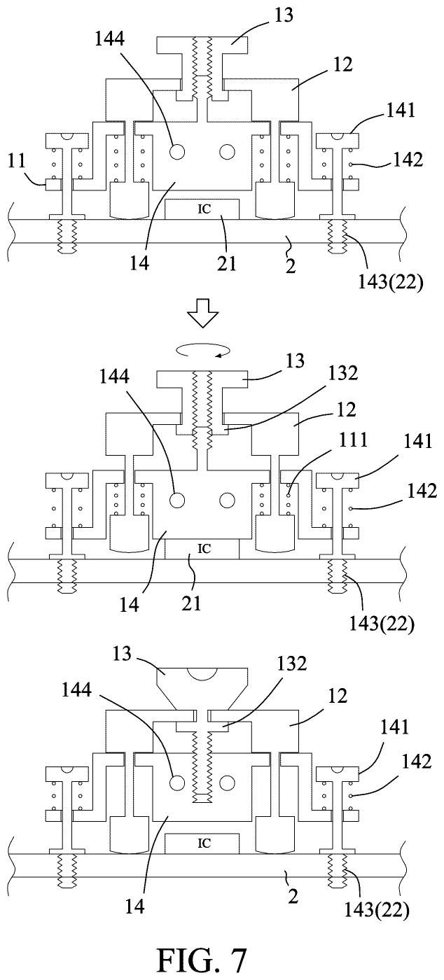

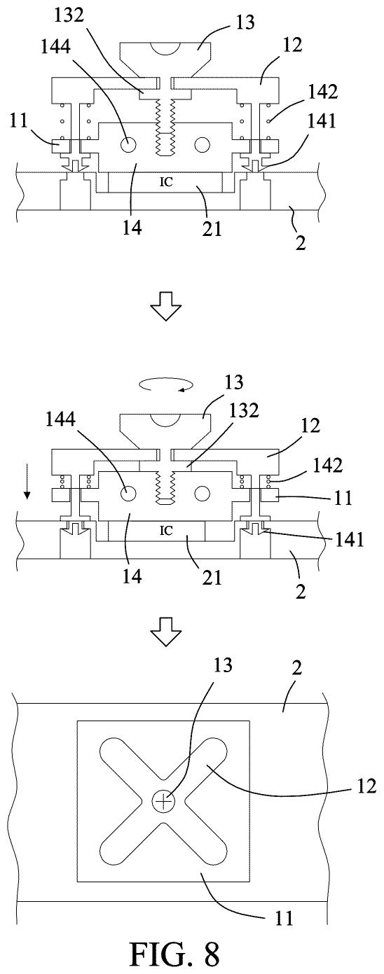

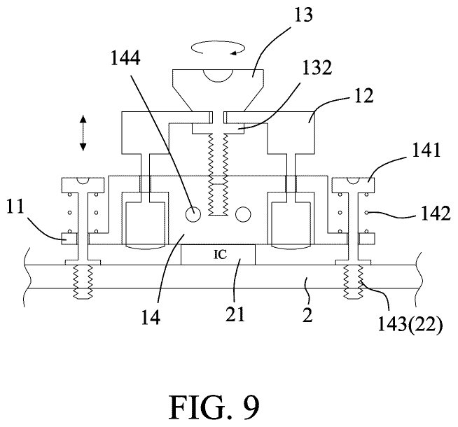

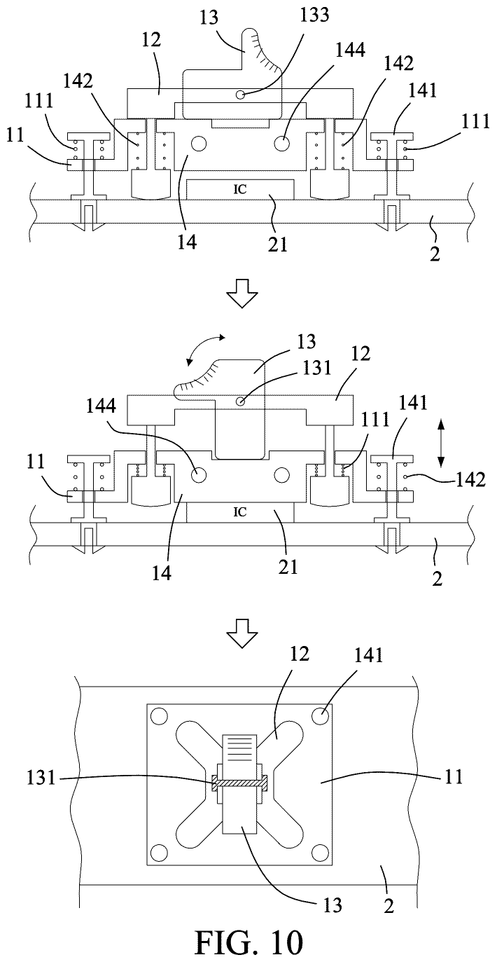

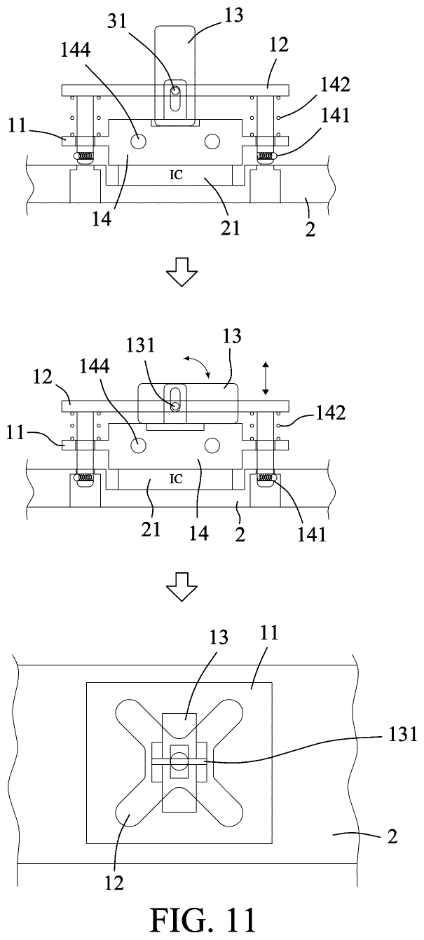

Besides the above embodiments, in an embodiment of the present disclosure, the difference from the above embodiments is that the actuating portion 13 and the retaining portion 12 can be integrally formed, or the actuating portion 13 and the retaining portion 12 are bolted by the bolting portion 131 (as shown in FIG. 10 and FIG. 11), or assembled by locking (as shown in FIG. 7), riveting, expanded connecting, welding, fastening or connecting (as shown in FIG. 6, FIG. 8 and FIG. 9); and thus, the actuating portion 13 can better meet actual assembling requirements.

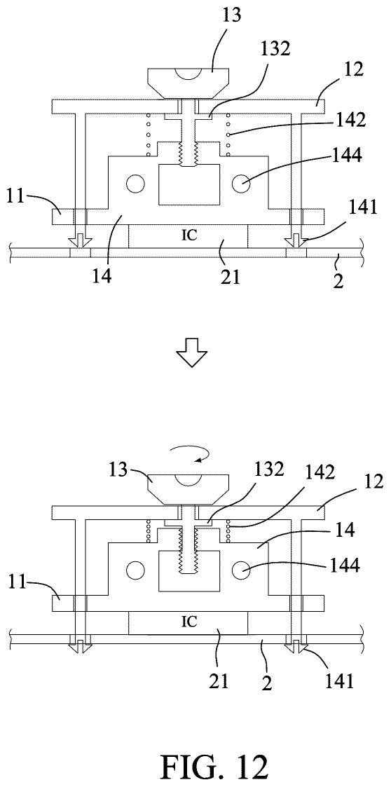

Besides the above embodiments, in an embodiment of the present disclosure, the difference from the above embodiments is that the actuating portion 13 is provided with a limiting portion 132 (as shown in FIG. 6 to FIG. 9, and FIG. 12), the limiting portion 132 is used for limiting, propping and restricting a stroke or restricting a distance from the actuating portion 13 to the radiator 14 or a joint stroke or a locking stroke; and thus, the actuating portion 13 can better meet actual assembling requirements.

Besides the above embodiments, in an embodiment of the present disclosure, the difference from the above embodiments is that the actuating portion 13 is a wrenching portion, the swirling portion, the motion portion and a lever portion, or is swirled, rotated, wrenched or actuated in a lever manner, so as to enable the actuating portion 13 to drive the retaining portion 12 to perform motion, actuation or up-down motion according to requirements; and thus, the actuating portion 13 can better meet actual assembling requirements.

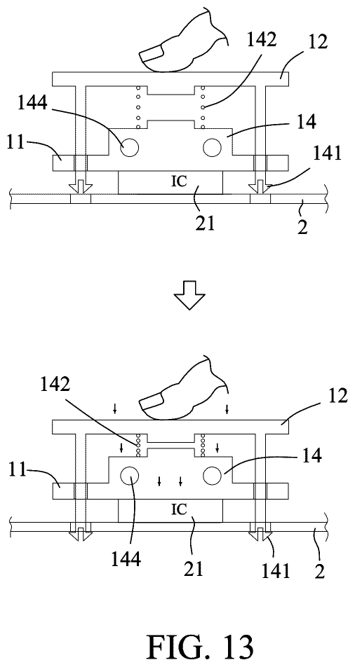

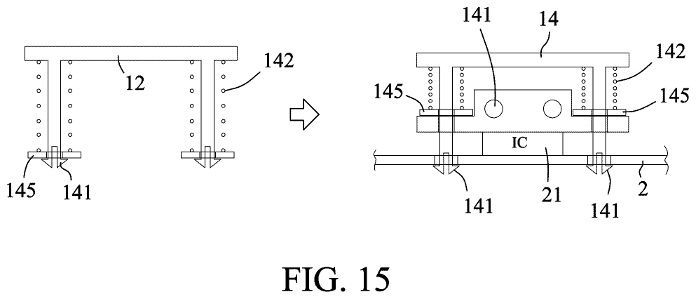

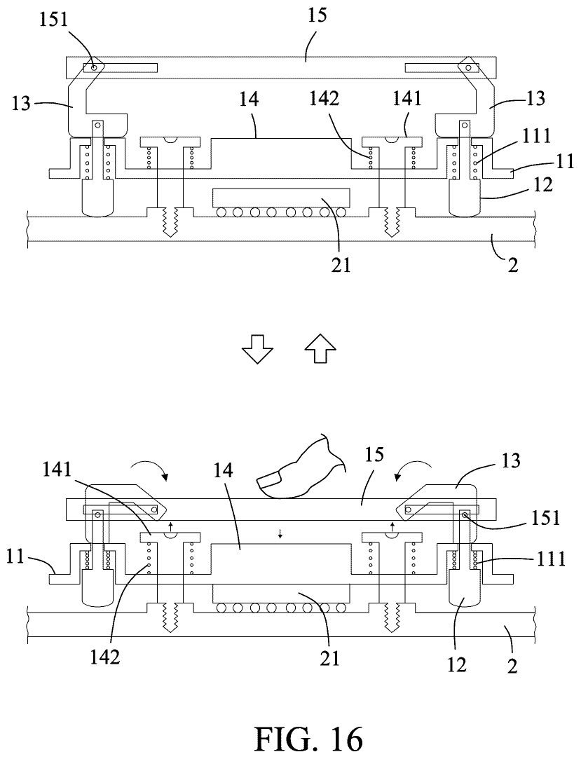

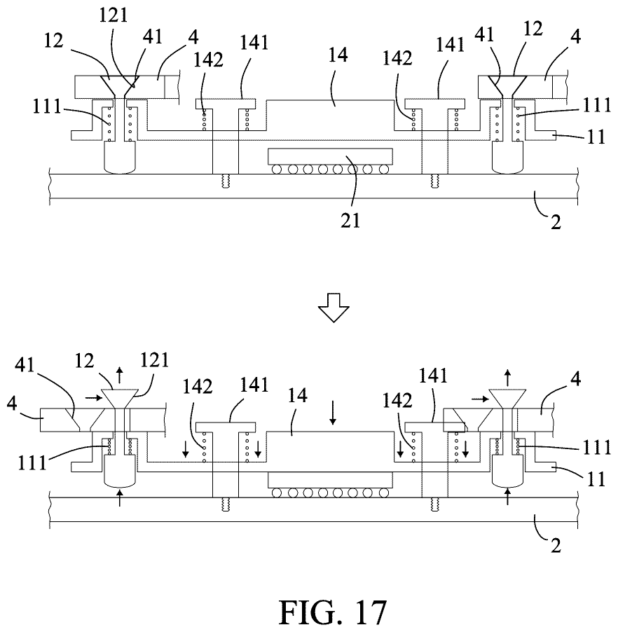

Besides the above embodiments, in an embodiment of the present disclosure, the difference from the above embodiments is that the fastening element 141 and the retaining portion 12 are integrally formed (as shown in FIG. 11, FIG. 12, FIG. 13, and FIG. 15), or the fastening element 141 and the main body portion 11 (the radiator 14 or the retaining portion 12) are assembled and formed (as shown in FIG. 6 to FIG. 10, FIG. 16, and FIG. 17); in addition, the fastening element 141 can be matched with a retaining member 145 to fasten the object 2 (as shown in FIG. 15); and thus, the fastening element 141 and the retaining portion 12 can better meet actual assembling requirements.

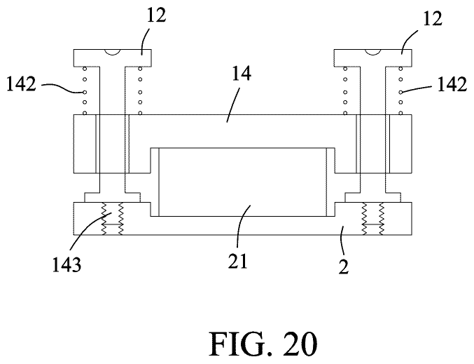

With reference to FIG. 20, as shown in the figure, besides the above embodiments, in an embodiment of the present disclosure, the difference from the above embodiments is that the main body portion 11 and the object 2 can be used as the radiators, where the main body portion 11 is connected to the object 2 by matching the retaining portion 12 with the fastening element 141, so that the heating element 21 is held between the main body portion 11 and the object 2 (namely two radiators) for double-sided heat radiation; and therefore, actual application requirements can be better met in the present disclosure.

The present disclosure has been disclosed in the above with preferred embodiment, but those familiar with this technique should understand that the embodiments are only used for describing the present disclosure and should not be construed as restricting the scope of the present disclosure. It is to be noted that all changes and substitutions equivalent to the embodiments should be set to cover the scope of the present disclosure. Therefore, the scope of protection of the present disclosure shall be subject to the definition of the scope of the patent application.

What is claimed is:

1. A retaining structure, comprising:
a main body portion;
at least one retaining portion movably arranged on the main body portion;
at least one actuating portion arranged on the retaining portion; and
a radiator arranged on the main body portion or integrally formed with the main body portion, wherein the radiator is provided with at least one fastening element and at least one elastomer; the fastening element is connected to an object, the object is provided with a heating element, or the object is a heating element, and the fastening element applies pressure to the radiator by way of the elastomer; and the actuating portion is operated to enable the retaining portion to retain or actuate on the object, so as to define an isolation space between the radiator and the heating element, or the actuating portion is operated to release the retaining portion from retaining the object, so as to enable the radiator to apply pressure to the heating element by way of the elastomer for heat dissipation.

2. A retaining structure, comprising:
a main body portion;
at least one retaining portion movably arranged on the main body portion; or
at least one actuating portion arranged on the retaining portion; or
a radiator arranged on the main body portion or integrally formed with the main body portion, wherein the radiator is provided with at least one fastening element or at least one elastomer, or the fastening element is connected to an object, or the object is provided with a heating element, or the object is a heating element; or the fastening element applies pressure to the radiator by way of the elastomer; or the actuating portion is operated to enable the retaining portion to retain or actuate on the object, or an isolation space is defined between the radiator and the heating element; or the actuating portion is operated to release the retaining portion from retaining the object, or the radiator applies pressure to the heating element by way of the elastomer for heat dissipation.

3. A retaining structure, comprising:
a main body portion;
at least one retaining portion movably arranged on the main body portion; or
at least one actuating portion arranged on the retaining portion; or
a radiator integrally formed with the main body portion or arranged on the main body portion.

4. A retaining structure, comprising:
a main body portion;
at least one retaining portion movably arranged on the main body portion; or
a radiator integrally formed with the main body portion or arranged on the main body portion.

5. The retaining structure according to claim 1, wherein the main body portion is provided with an elastic element, and the elastic element provides an elastic force for the retaining portion to retain the object or the radiator or the heating element.

6. The retaining structure according to claim 2, wherein the main body portion is provided with an elastic element, and the elastic element provides an elastic force for the retaining portion to retain the object or the radiator or the heating element.

7. The retaining structure according to claim 1, wherein the retaining structure is provided with at least one elastomer, or the main body portion is provided with an elastic element, or an elastic force of the elastic element is greater than that of the elastomer, or the elastic force of the elastomer is greater than that of the elastic element.

8. The retaining structure according to claim 2, wherein the retaining structure is provided with at least one elastomer, or the main body portion is provided with an elastic element, or an elastic force of the elastic element is greater than that of the elastomer, or the elastic force of the elastomer is greater than that of the elastic element.

9. The retaining structure according to claim 3, wherein the retaining structure is provided with at least one elastomer, or the main body portion is provided with an elastic element, or an elastic force of the elastic element is greater than that of the elastomer, or the elastic force of the elastomer is greater than that of the elastic element.

10. The retaining structure according to claim 4, wherein the retaining structure is provided with at least one elastomer, or the main body portion is provided with an elastic element, or an elastic force of the elastic element is greater than that of the elastomer, or the elastic force of the elastomer is greater than that of the elastic element.

11. The retaining structure according to claim 1, wherein one, two, more than two or four retaining structures are provided, or the retaining structures are respectively connected by a connecting portion, or the retaining structures are respectively linked by the connecting portion.

12. The retaining structure according to claim 2, wherein one, two, more than two or four retaining structures are provided, or the retaining structures are respectively connected by a connecting portion, or the retaining structures are respectively linked by the connecting portion.

13. The retaining structure according to claim 3, wherein one, two, more than two or four retaining structures are provided, or the retaining structures are respectively connected by a connecting portion, or the retaining structures are respectively linked by the connecting portion.

14. The retaining structure according to claim 4, wherein one, two, more than two or four retaining structures are provided, or the retaining structures are respectively connected by a connecting portion, or the retaining structures are respectively linked by the connecting portion.

15. The retaining structure according to claim 1, wherein a plurality of retaining portions are provided, or the retaining portions are respectively connected by a connecting portion, or the connecting portions are respectively provided with a restricting portion, or when the retaining portions or the connecting portions move, the restricting portions are used for restricting to operate the fastening element with a tool, or allowing to use the tool to operate the fastening element; or the retaining structure is provided with a restricting portion for restricting to operate the fastening element with the tool, or allowing to use the tool to operate the fastening element.

16. The retaining structure according to claim 2, wherein a plurality of retaining portions are provided, or the retaining portions are respectively connected by a connecting portion, or the connecting portions are respectively provided with a restricting portion, or when the retaining portions or the connecting portions move, the restricting portions are used for restricting to operate the fastening element with a tool, or allowing to use the tool to operate the fastening element; or the retaining structure is provided with a restricting portion for restricting to operate the fastening element with the tool, or allowing to use the tool to operate the fastening element.

17. The retaining structure according to claim 1, wherein one, two, more than two, four or more than four retaining portions are provided, or a connecting portion is arranged between every two retaining portions to retain an object, or the retaining portions are connected to the connecting portions in a bolting manner; or the retaining portions are inserted, buckled, entered or propped by a transverse object or an object, or the retaining portions are enabled to move or perform motion, or the retaining portions or the transverse object or the object is provided with an inclined surface, an arc surface or a lifting portion for lifting or moving the retaining portions.

18. The retaining structure according to claim 2, wherein one, two, more than two, four or more than four retaining portions are provided, or a connecting portion is arranged between every two retaining portions to retain an object, or the retaining portions are connected to the connecting portions in a bolting manner; or the retaining portions are inserted, buckled, entered or propped by a transverse object or an object, or the retaining portions are enabled to move or perform motion, or the retaining portions or the transverse object or the object is provided with an inclined surface, an arc surface or a lifting portion for lifting or moving the retaining portions.

19. The retaining structure according to claim 3, wherein one, two, more than two, four or more than four retaining portions are provided, or a connecting portion is arranged between every two retaining portions to retain an object, or the retaining portions are connected to the connecting portions in a bolting manner; or the retaining portions are inserted, buckled, entered or propped by a transverse object or an object, or the retaining portions are enabled to move or perform motion, or the retaining portions or the transverse object or the object is provided with an inclined surface, an arc surface or a lifting portion for lifting or moving the retaining portions.

20. The retaining structure according to claim 4, wherein one, two, more than two, four or more than four retaining portions are provided, or a connecting portion is arranged between every two retaining portions to retain an object, or the retaining portions are connected to the connecting portions in a bolting manner; or the retaining portions are inserted, buckled, entered or propped by a transverse object or an object, or the retaining portions are enabled to move or perform motion, or the retaining portions or the transverse object or the object is provided with an inclined surface, an arc surface or a lifting portion for lifting or moving the retaining portions.

21. The retaining structure according to claim 3, wherein the radiator is provided with at least one fastening element or a limiting element, and the fastening element or the limiting element is connected to an object, limits the object or retains the object so as to restrict the motion, position, motion direction, elastic motion, rotating, swirling of the radiator or prevent from rotating or swirling.

22. The retaining structure according to claim 4, wherein the radiator is provided with at least one fastening element or a limiting element, and the fastening element or the limiting element is connected to an object, limits the object or retains the object so as to restrict the motion, position, motion direction, elastic motion, rotating, swirling of the radiator or prevent from rotating or swirling.

23. The retaining structure according to claim 1, wherein the retaining structure comprises an object and a heating element, the main body portion or the object is the radiator, or the main body portion is connected to the radiator and the object is the radiator, or the heating element is held between the two radiators for heat dissipation or double-sided heat dissipation.

24. The retaining structure according to claim 2, wherein the retaining structure comprises an object and a heating element, the main body portion or the object is the radiator, or the main body portion is connected to the radiator and the object is the radiator, or the heating element is held between the two radiators for heat dissipation or double-sided heat dissipation.

25. The retaining structure according to claim 3, wherein the retaining structure comprises an object and a heating element, the main body portion or the object is the radiator, or the main body portion is connected to the radiator and the object is the radiator, or the heating element is held between the two radiators for heat dissipation or double-sided heat dissipation.

26. The retaining structure according to claim 4, wherein the retaining structure comprises an object and a heating element, the main body portion or the object is the radiator, or the main body portion is connected to the radiator and the object is the radiator, or the heating element is held between the two radiators for heat dissipation or double-sided heat dissipation.
